(19) United States
(12) Patent Application Publication
(10) Pub. No.: US 2020/0103983 A1
(43) Pub. Date: Apr. 2, 2020

(54) STARTING METHOD FOR INPUTTING MORSE CODE AND PORTABLE ELECTRONIC DEVICE THEREOF

(71) Applicant: GETAC TECHNOLOGY CORPORATION, Hsinchu County (TW)

(72) Inventor: KUO-YANG TSENG, Taipei City (TW)

(21) Appl. No.: 16/146,981

(22) Filed: Sep. 28, 2018

(51) Int. Cl. G06F 3/023; H04L 15/06; H03K 17/967

(52) U.S. Cl. CPC G06F 3/0235; H03K 17/967; H04L 15/06

(57) ABSTRACT

A starting method for inputting Morse code and a portable electronic device thereof are provided. The starting method for inputting Morse code is performed in the portable electronic device that includes a first physical button, a second physical button, a sensing circuit and a processing circuit. The starting method for inputting Morse code includes steps of: when the portable electronic device is switched to a sleep mode or a shutdown mode, enabling the sensing circuit to sense whether the first physical button and the second physical button are simultaneously pressed by a user; and when the first physical button and the second physical button are simultaneously pressed by the user, enabling the processing circuit to generate a longer mark of Morse code or a shorter mark of Morse code according to the duration for which the user presses the first physical button or the second physical button.

### BACKGROUND OF THE INVENTION

### Field of the Invention

The present invention relates to a starting method and more particularly, to a starting method for inputting Morse code and a portable electronic device thereof.

### Description of the Prior Art

In the prior art, a button on a portable electronic device can be pressed to input Morse code. However, during the inputting process, the portable electronic device is frequently required to be in an operating mode, i.e., a state in which a screen is lit. Thus, when a user in an emergency wishes to secretively input Morse code through a portable electronic device, the above prior art cannot satisfy such need.

### SUMMARY OF THE INVENTION

In view of the above, it is an object of the present invention to provide a starting method for inputting Morse code when a portable electronic device is in a sleep mode or shutdown mode and a portable electronic device thereof.

To achieve the above object, a starting method for inputting Morse code is provided according to an embodiment of the present invention. The starting method is performed in a portable electronic device that includes a first physical button, a second physical button, a sensing circuit and a processing circuit. The starting method includes the following steps: when the portable electronic device is switched to a sleep mode or a shutdown mode, enabling the sensing circuit to sense whether the first physical button and the second physical button are simultaneously pressed by a user; and when the first physical button and the second physical button are simultaneously pressed by the user, enabling the processing circuit to generate a longer mark of Morse code or a shorter mark of Morse code according to the duration for which the user presses the first physical button or the second physical button. A portable electronic device is further provided according to another embodiment of the present invention. The portable electronic device includes a first physical button, a second physical button, a sensing circuit, a processing circuit and a storage device. The storage device stores an application for instructing the portable electronic device to perform the starting method of the foregoing embodiment.

To better understand the features and technical contents of the present invention, detailed description associated with the present invention are given with the accompanying drawings below. It should be noted that, the detailed description and drawings are only for illustrating the present invention and are not to be construed as limitations to the claim scope of the present invention.

### BRIEF DESCRIPTION OF THE DRAWINGS

FIG. 1 is a flowchart of a starting method for inputting Morse code according to an embodiment of the present invention; and

FIG. 2 is a function block diagram of a portable electronic device according to an embodiment of the present invention.

### DETAILED DESCRIPTION OF THE EMBODIMENTS

The present invention is described in detail in the following embodiments with the accompanying drawings below. However, the concepts of the present invention can be realized in numerous different forms and are not limited to the explanations of the illustrative embodiments in the disclosure. Furthermore, the same reference numerals in the drawings can represent similar elements.

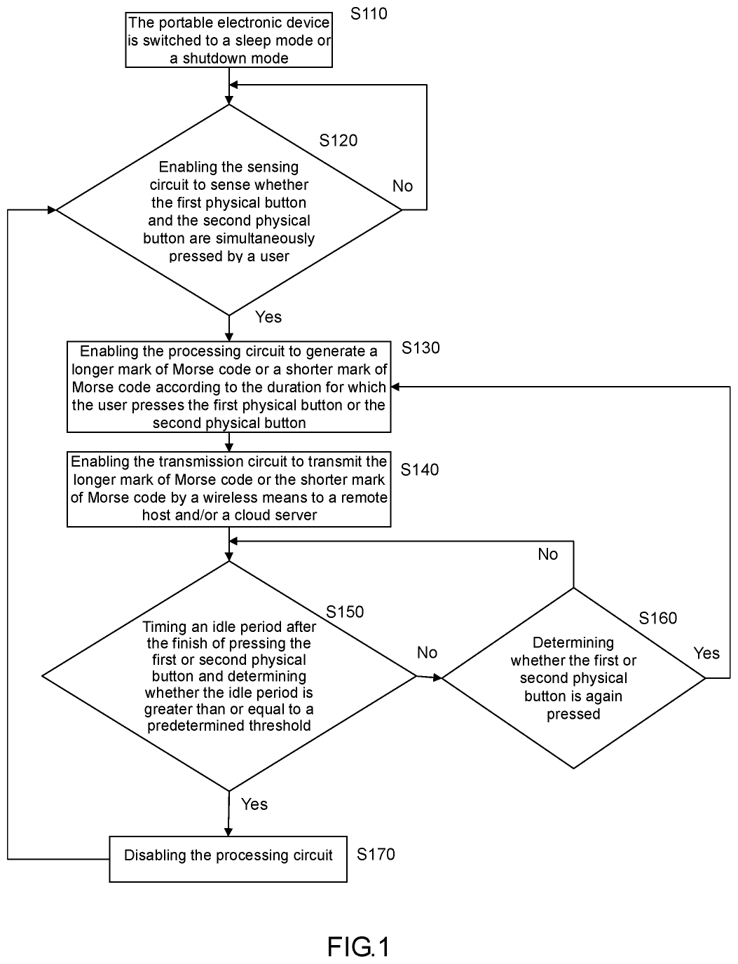

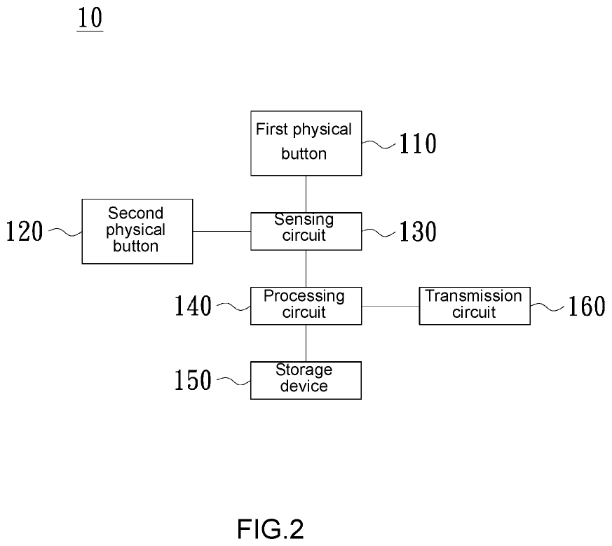

Refer to FIG. 1 and FIG. 2 first. FIG. 1 shows a flowchart of a starting method for inputting Morse code provided by an embodiment of the present invention. FIG. 2 shows a function block diagram of a portable electronic device provided by an embodiment of the present invention. It should be noted that, the starting method in FIG. 1 may be performed in the portable electronic device 10 in FIG. 2. However, the present invention does not limit a specific implementation of the portable electronic device 10 in FIG. 2, and a person skilled in the art can conduct related designs of the portable electronic device 10 according to actual requirements or applications. As shown in FIG. 2, the portable electronic device 10 primarily includes a first physical button 110, a second physical button 120, a sensing circuit 130 and a processing circuit 140. The sensing circuit 130 and the processing circuit 140 may be implemented by pure hardware circuits, or by firmware or software in conjunction with hardware circuits. In sum, the present invention does not limit the specific implementation of the sensing circuit 130 and the processing circuit 140. Furthermore, the sensing circuit 130 and the processing circuit 140 may be, for example but not limited to, integratedly or separately provided.

It is known from the prior art that, the starting method in FIG. 1 may be implemented by an application (not shown) having a plurality of instructions, wherein the application is stored in the storage device 150 and is for instructing the portable electronic device 10 to perform the starting method in FIG. 1. That is to say, when the portable electronic device 10 is installed with the application, the portable electronic device 10 is capable of performing the starting method in FIG. 1. It should be noted that, the present invention does not limit the specific implementation for installing the application in the portable electronic device 10, and a person skilled in the art can conduct related designs according to actual requirements or applications. Furthermore, the storage device 150 may be directly integrated in the portable electronic device 10, as shown in FIG. 2, or may be separately provided outside the portable electronic device 10. In sum, the present invention does not limit the specific implementation of the storage device 150.

More specifically, as shown in FIG. 1, in step S110, when the portable electronic device 10 is switched to a sleep mode or a shutdown mode, the embodiment performs step S120. In step S120, the embodiment enables the sensing circuit 130 to sense whether the first physical button 110 and the second physical button 120 are simultaneously pressed by a user (not shown). If so, step S130 is performed; if not, step S120 is iterated. In step S130, the embodiment enables the processing circuit 140 to generate, according to the duration for which the user presses the first physical button 110 or the second physical button 120, a longer mark of Morse code or a shorter mark of Morse code, i.e., a dash (-) or a dot (.). For illustration purposes, it is first assumed that the first physical button 110 and the second physical button 120 in this embodiment are respectively a volume up button and a volume down button on the portable electronic device 10; however, the above is not to be construed as limitations to the present invention.

It should be noted that, even if the processing circuit 140 is enabled to generate a longer mark of Morse code or a shorter mark of Morse code, the embodiment can still enable the portable electronic device 10 to be in a sleep mode or a shutdown mode without requiring the screen to be lit. Thus, on the basis of the teaching of the above disclosure, a person skilled in the art can understand that, the embodiment focuses on a feature that, when the portable electronic device 10 is in a sleep mode or a shutdown mode, the portable electronic device 10 can be enabled to enter a process for inputting Morse code by having a user press two physical buttons in combination on the portable electronic device 10, i.e., simultaneously pressing the first physical button 10 and the second physical button 120. Therefore, compared to the prior art, the embodiment better provides ideal concealment and convenience. That is to say, the embodiment satisfies the requirement of secretively inputting Morse code through the portable electronic device 10 when a user is in a restricted environment such as an emergency.

Furthermore, as shown in FIG. 2, the portable electronic device 10 may further include a transmission circuit 160 that may be implemented through pure hardware circuits, or may be implemented by firmware or software in conjunction with hardware circuits. In sum, the present invention does not limit the specific implementation of the transmission circuit 160. Further, the transmission circuit 160 may be directly integrated in the portable electronic device 10, as shown in

FIG. 2, or be separately provided outside the portable electronic device 10. However, the present invention is not limited to the above. Correspondingly, the starting method in FIG. 1 may further include step S140. In step S140, the embodiment enables the transmission circuit 160 to transmit the foregoing longer mark of Morse code or shorter mark of Morse code by a wireless means to a remote host (not shown) and/or a cloud server (not shown). That is to say, the remote host and/or the cloud server may receive the longer mark of Morse code or shorter mark of Morse code generated by the processing circuit 140 through the transmission circuit 160. In addition, even if the transmission circuit 160 is enabled to transmit the longer mark of Morse code or shorter mark of Morse code, the embodiment is nonetheless capable of enabling the portable electronic device 10 to be in a sleep mode or a shutdown mode. Therefore, compared to the prior art, the embodiment provides the transmission process of Morse code with even better concealment.

Further, it is assumed that in step S130 of this embodiment that, if the duration for which the user presses the first physical button 110 or the second physical button 120 is between 0.08 s and 0.12 s, a shorter mark of Morse code is generated; if the duration for which the user presses the first physical button 110 or the second physical button 120 is between 0.28 s and 0.32 s, a longer mark of Morse code is generated; however, the present invention is not limited to the above examples. In other embodiments, the process for generating the foregoing longer mark of Morse code or shorter mark of Morse code may also be determined by the processing circuit 140 directly according to whether the user presses the first physical button 110 or the second physical button 120. For example, if the user presses the first physical button 110, a shorter mark of Morse code is generated; if the user presses the second physical button 120, a longer mark of Morse code is generated. In sum, the present invention does not limit the specific implementation of the process for generating a longer mark of Morse code or shorter mark of Morse code.

It should be understood that, the Morse code that a user wishes to input is usually more than one longer mark of Morse code or one shorter mark of Morse code. Thus, in step S150 after step S130, the processing circuit 140 further times an idle period continuously after the user has finished pressing the first physical button 110 or the second physical button 120, and determines whether the idle period is greater than or equal to a predetermined threshold, e.g., 0.5 s. If not, step S160 is performed; if so, step S170 is performed. In step S160, the processing circuit 140 again determines whether the first physical button 110 or the second physical button 120 is again pressed by the user. If not, step S150 is iterated; if so, step S130 is iterated. That is to say, when the idle period is not greater than or equal to the predetermined threshold and the first physical button 110 or the second physical button 120 is again pressed by the user, the embodiment enables the processing circuit 140 to generate a (new) longer mark of Morse code or shorter mark of Morse code according to the duration for which the user presses the first physical button 110 or the second physical button 120. Correspondingly, when the idle period is greater than or equal to the predetermined threshold, the processing circuit 140 determines that the user has finished inputting of Morse code. Thus, in step S170, the embodiment disables the processing circuit 140, and step S120 is iterated.

For example, in this embodiment, it is assumed that when the Morse code that the user wishes to input is “.-”, the processing circuit 140 first generates the shorter mark of Morse code “.” because the duration for which the user presses the first physical button 110 or the second physical button 120 is between 0.08 s and 0.12 s. After a period of pause, i.e., a first idle period T(1) after the user has finished pressing the first physical button 110 or the second physical button 120 for the first time and the first idle period T(1) is not more than 0.5 s, assume that the user again presses the first physical button 110 or the second physical button 120 for the second time. Since the duration for which the user presses the first physical button 110 or the second physical button 120 for the second time is between 0.28 s and 0.32 s, the processing circuit 140 again generates a longer mark of Morse code “-”.

Finally, after another period of pause, i.e., a second idle period T(2) after the user has finished pressing the first physical button 110 or the second physical button 120 for the second time, the second idle period T(2) is inevitably more than 0.5 s because the user has finished inputting the set of Morse code “. -”. Thus, the embodiment ends the inputting process of the set of Morse code “. -”, i.e., disabling the processing circuit 140, and the process returns to the step in which the sensing circuit 130 senses whether the first physical button 110 and the second physical button 120 are simultaneously pressed by a user and awaits for a next inputting process of Morse code to begin. It should be understood that, step S140, step S150 and step S160 in FIG. 1 are steps that can be performed in parallel without any conflict. Alternatively, in other embodiments, the application may relocate step S140 to a loop subsequent to steps S130, S150 and S160 and perform S140 accordingly. That is to say, only after the user has finished inputting the set of Morse code “. -”, the transmission circuit 160 is then enabled to transmit the shorter mark of Morse code “.” and the longer mark of Morse code “-” to the remote host and/or cloud server according to the inputting sequence. In conclusion, the above does not affect the implementation of the present invention. Since associated details are identical to those described in the foregoing disclosure, they are omitted herein.

In conclusion, in the starting method for inputting Morse code and the portable electronic device thereof provided by the embodiments of the present invention, when the portable electronic device is in a sleep mode or a shutdown mode, the portable electronic device can be enabled to enter a process for inputting Morse code by having a user press two physical buttons in combination on the portable electronic device, i.e., simultaneously pressing a first physical button and a second physical button. Therefore, compared to the prior art, the embodiment better provides ideal concealment and convenience. That is to say, the embodiment satisfies the requirement of secretively inputting Morse code through the portable electronic device when a user is in a restricted environment such as an emergency.

The detailed description above is merely associated with the embodiments of the present invention, and such embodiments are not to be construed as limitations to the scope of the present invention.

1. A starting method for inputting Morse code, performed in a portable electronic device, the portable electronic device comprising a first physical button, a second physical button, a sensing circuit and a processing circuit, the starting method comprising:
when the portable electronic device is switched to a sleep mode or a shutdown mode, enabling the sensing circuit to sense whether the first physical button and the second physical button are simultaneously pressed by a user; and
when the first physical button and the second physical button are simultaneously pressed by the user, enabling the processing circuit to generate a longer mark of Morse code or a shorter mark of Morse code according to the duration for which the user presses the first physical button or the second physical button while maintaining the portable electronic device in the sleep or shutdown mode.

2. The starting method according to claim 1, wherein the portable electronic device further comprises a transmission circuit, the starting method further comprising:
enabling the transmission circuit to transmit the longer mark of Morse code or the shorter mark of Morse code by a wireless means to a remote host and/or a cloud server while maintaining the portable electronic device in the sleep or shutdown mode.

3. The starting method according to claim 1, wherein after the step of enabling the processing circuit to generate the longer mark of Morse code or the shorter mark of Morse code according to the duration for which the user presses the first physical button or the second physical button, the processing circuit further times an idle period continuously after the user has finished pressing the first physical button or the second physical button and determines whether the idle period is greater than or equal to a predetermined threshold.

4. The starting method according to claim 3, wherein when the idle period is not greater than or equal to the predetermined threshold and the first physical button or the second physical button is again pressed by the user, the step of enabling the processing circuit to generate the longer mark of Morse code or the shorter mark of Morse code according to the duration for which the user presses the first physical button or the second physical button is iterated.

5. The starting method according to claim 4, wherein when the idle period is greater than or equal to the predetermined threshold, the processing circuit is disabled, and the step of enabling the sensing circuit to sense whether the first physical button and the second physical button are simultaneously pressed by the user is iterated.

6. A portable electronic device, comprising:
a first physical button;
a second physical button;
a sensing circuit;
a processing circuit; and
a storage device, storing an application for instructing the portable electronic device to perform a starting method for inputting Morse code, wherein the starting method comprises:
when the portable electronic device is switched to a sleep mode or a shutdown mode, enabling the sensing circuit to sense whether the first physical button and the second physical button are simultaneously pressed by a user; and
when the first physical button and the second physical button are simultaneously pressed by the user, enabling the processing circuit to generate a longer mark of Morse code or a shorter mark of Morse code according to the duration for which the user presses the first physical button or the second physical button while maintaining the portable electronic device remains in the sleep or shutdown mode.

7. The portable electronic device according to claim 6, further comprising a transmission circuit, wherein the starting method further comprises:
enabling the transmission circuit to transmit the longer mark of Morse code or the shorter mark of Morse code by a wireless means to a remote host and/or a cloud server while maintaining the portable electronic device remains in the sleep or shutdown mode.

8. The portable electronic device according to claim 6, wherein after the step of enabling the processing circuit to generate the longer mark of Morse code or the shorter mark of Morse code according to the duration for which the user presses the first physical button or the second physical button, the processing circuit further times an idle period continuously after the user has finished pressing the first physical button or the second physical button and determines whether the idle period is greater than or equal to a predetermined threshold.

9. The portable electronic device according to claim 8, wherein when the idle period is not greater than or equal to the predetermined threshold and the first physical button or the second physical button is again pressed by the user, the step of enabling the processing circuit to generate the longer mark of Morse code or the shorter mark of Morse code according to the duration for which the user presses the first physical button or the second physical button is iterated.

10. The portable electronic device according to claim 9, wherein when the idle period is greater than or equal to the predetermined threshold, the processing circuit is disabled, and the step of enabling the sensing circuit to sense whether the first physical button and the second physical button are simultaneously pressed by the user is iterated.

11. A starting method for inputting Morse code, performed in a portable electronic device, the portable electronic device comprising a first physical button, a second physical button, a sensing circuit and a processing circuit, the starting method comprising:
when the portable electronic device is switched to a sleep mode or a shutdown mode, enabling the sensing circuit to sense whether the first physical button and the second physical button are simultaneously pressed by a user; and
when the first physical button and the second physical button are simultaneously pressed by the user, enabling the processing circuit to generate a longer mark of Morse code or a shorter mark of Morse code according to the duration for which the user presses the first physical button or the second physical button without turning on a screen of the portable electronic device.

12. The starting method according to claim 11, wherein the portable electronic device further comprises a transmission circuit, the starting method further comprising:
enabling the transmission circuit to transmit the longer mark of Morse code or the shorter mark of Morse code by a wireless means to a remote host and/or a cloud server without turning on the screen of the portable electronic device.

13. The starting method according to claim 11, wherein after the step of enabling the processing circuit to generate the longer mark of Morse code or the shorter mark of Morse code according to the duration for which the user presses the first physical button or the second physical button, the processing circuit further times an idle period continuously after the user has finished pressing the first physical button or the second physical button and determines whether the idle period is greater than or equal to a predetermined threshold.

14. The starting method according to claim 13, wherein when the idle period is not greater than or equal to the predetermined threshold and the first physical button or the second physical button is again pressed by the user, the step of enabling the processing circuit to generate the longer mark of Morse code or the shorter mark of Morse code according to the duration for which the user presses the first physical button or the second physical button is iterated.

15. The starting method according to claim 14, wherein when the idle period is greater than or equal to the predetermined threshold, the processing circuit is disabled, and the step of enabling the sensing circuit to sense whether the first physical button and the second physical button are simultaneously pressed by the user is iterated.
